(19) United States
(12) Patent Application Publication
(10) Pub. No.: US 2005/0184320 A1
(43) Pub. Date: Aug. 25, 2005

(54) Photoconductor having an embedded contact electrode

(76) Inventors: Michael C. Green, Palo Alto, CA (US); Steve G. Bandy, Sunnyvale, CA (US); Larry D. Partain, Los Altos, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/064,360

(22) Filed: Feb. 22, 2005

Related U.S. Application Data
(60) Provisional application No. 60/546,555, filed on Feb. 20, 2004.

(51) Int. Cl. H01L 29/94

(52) U.S. Cl. 257/290

(57) ABSTRACT

A photodetector device comprising a contact electrode embedded within a semiconductor material.

### PRIORITY

The present patent application claims priority to corresponding provisional patent application No. 60/546,555, entitled “Photoconductor Having an Embedded Contact Electrode,” filed on Feb. 20, 2004.

### TECHNICAL FIELD

Embodiments of the present invention pertain to the field of photodetectors and, more specifically, to semiconductor based radiation detectors.

### BACKGROUND

Detectors may be fabricated in many ways, and may serve many purposes. For all detectors, sensitivity and signal-to-noise ratio is important to successful operation. When attempting to detect x-rays, photodetectors are preferably highly sensitive to x-rays and relatively insensitive to other electromagnetic radiation. Photodetectors are constructed with photoconductor sensors. The photoconductors can be intrinsic semiconductor materials that have high resistivity unless illuminated by photons.

Photodetectors function by accumulating charge on capacitors generated by pixels of p-i-n photodiodes (amorphous silicon or organic semiconductor) with scintillators or by pixels of photoconductors. Typically, many pixels are arranged over a surface of the imager where TFTs (or single and/or double diodes) at each pixel connect the charged capacitor to a read out amplifier at the appropriate time. A pixel is composed of the scintillator/photodiode/capacitor/TFT or switching-diode combination or by the photoconductor/capacitor/TFT or switching-diode combination.

FIG. 1A illustrates one type of conventional photodetector 100 that includes a semiconductor material 120 with a pair of contact electrodes, top and bottom contact electrodes 110 and 130, on either side of the semiconductor material 120. The semiconductor material 120, upon which radiation 180 is incident through the top contact electrode 110, acts as a direct conversion layer to convert incident radiation 180 to electric currents. A voltage source 160 connected to the electrodes applies a positive bias voltage across the semiconductor material 120, and current is observed as an indication of the magnitude of incident radiation 180. When no radiation is present, the resistance of the semiconductor material 120 is high for most photoconductors, and only a small dark current can be measured. When radiation 180 is made incident upon the semiconductor material 120, through the top contact electrode 110, electron-hole pairs form and drift apart under the influence of a voltage across that region. Electrons are drawn toward the more positively (+) biased contact electrode, the top contact electrode 110, and holes are drawn toward the more negatively biased (e.g., quasi-grounded by circuitry 170) bottom contact electrode 130. Formation of electron-hole pairs occurs due to interaction between the incident radiation 180 and the semiconductor material 120. If the x-rays have energy greater than the band gap energy of the semiconductor material 120, then electron-hole pairs are generated in the semiconductor material 120 as each photon is absorbed in the material. If a voltage is being continuously applied across the semiconductor material 120, the electron and hole will tend to separate, thereby creating a current flowing through the photodetector 100. The magnitude of the current produced in the photodetector 100 is related to the magnitude of the incident radiation 180 received. After removal of the incident radiation 180, the charge carriers (electrons and holes) remain for a finite period of time until they either reach the collection electrodes or can be recombined. The term “charge carriers” is often used to refer to either the electrons, or holes, or both.

FIG. 1B illustrates a prior configuration of a semiconductor photocathode apparatus 101 discussed in U.S. Pat. No. 5,923,045. Apparatus 101 includes a substrate 141, a contact layer 111, a surface electrode 112, a first semiconductor material 121, a second semiconductor material 122, a third semiconductor material 123, and a fourth semiconductor material 124. The fourth semiconductor material 124 is a semiconductor section (channel grid) and is embedded within the second semiconductor material 122. The first semiconductor material 121 is coupled to the substrate 141 and the second semiconductor material 122. The fourth semiconductor material 124 has a different dopant concentration than the second semiconductor material 122 and may have a mesh form. The embedded mesh-shaped fourth semiconductor material 124 is used as a potential barrier to bend the orbit of the electrons towards the anode (not shown). The contact layer 111 is formed partially over the surface of the second semiconductor material 122 and may have a mesh- or grid-shape. Contact layer 111 forms a p-n junction with the second semiconductor material 122 and the contact layer 111. The surface electrode 112 is disposed on the contact layer 111. The third semiconductor material 123 is formed on top of the surface electrode 112, the contact layer 111, and the remaining surfaces of the second semiconductor material 122. The third semiconductor material 123 has a lower work function than the second semiconductor material 122. The second semiconductor material 122 and the third semiconductor material 123 are different semiconductor materials, such as p-type InP for the second semiconductor material 122 and CsO for the third semiconductor material 123.

A problem with prior configurations such as the photocathode apparatus 101 is the difficulty in forming a surface electrode 112 to the photoconductor material (second semiconductor material 122). This problem results in lack of repeatability in the initial electrical characteristics of the surface electrode 112. Another problem is the chemical reactions between the contact layer 111 and the second semiconductor material 122, as well as the surface electrode 112 and the third semiconductor material 123.

Among semiconductor materials considered for x-ray detectors are selenium, mercuric iodide and lead iodide. The two iodide compounds have a higher mobility product, require a much lower polarizing voltage than selenium, and have additional advantages such as greater temperature stability. However, each of mercuric iodide and lead iodide has physical parameters that effect their performance and ease of use in single layer x-ray detectors.

In mercuric iodide, the carrier mobility is measured to be higher than lead iodide and the lag time is found to be lower. This means that it is difficult to use a thick layer of lead iodide, which is more efficient in absorbing a greater fraction of incident x-ray photons, especially at higher photon energies that increase detector sensitivity. However, mercuric iodide is more chemically reactive toward typical contact electrodes (e.g., aluminum) than is lead iodide and considerable problems have been experienced with contact corrosion in flat panel detectors coated with mercuric iodide.

Carbon (graphite) is an alternative choice as a conductive contact electrode. It is chemically unreactive towards the iodide photoconductor. It neither forms amalgams with metallic mercury nor reacts to abstract iodine from the photoconductor. However, if the carbon is applied to the top surface of the photoconductor material in liquid form as a finely divided colloidal suspension (Aquadag), which dries to give an adherent conductive coating, there is high probability of carbon particles being carried down into the iodide material along cracks and grain boundaries. This produces inconsistent contact characteristics from point to point with partial short-circuiting through the photoconductor material, which means that the effective thickness of the charge collection layer varies across a panel.

Another prior method of applying carbon to the top surface of the photoconductor material is by sputtering. This avoids the problem of carbon particles suspended in a liquid medium being carried down cracks. However, the sputter-deposited carbon film typically contains a high degree of internal stress. Additionally, the sputter-deposited carbon film has a very low coefficient of thermal expansion, which presents a severe expansion mismatch with the underlying iodide material. These factors, coupled with the lack of chemical interaction between carbon and the iodide (which means that carbon does not from strong bonds at the interface), cause the adhesion of the sputter-deposited carbon film to the photoconductor material to be problematic.

### SUMMARY OF AN EMBODIMENT

A photodetector is described. In one embodiment, the photodetector comprises a first semiconductor material, and a first contact electrode embedded within the first semiconductor material.

In another embodiment, the first contact electrode is a mesh. The mesh comprises apertures wherein the first semiconductor material is disposed through the apertures to embed the first contact electrode within the first semiconductor material.

Additional features and advantages of the present invention will be apparent from the accompanying drawings, and from the detailed description that follows below.

### BRIEF DESCRIPTION OF THE DRAWINGS

The present invention is illustrated by way of example and not intended to be limited by the figures of the accompanying drawings.

FIG. 1A illustrates one configuration of a conventional photodetector.

FIG. 1B illustrates another configuration of a conventional photodetector.

FIG. 2A illustrates one embodiment of a photodetector having an embedded contact electrode.

FIG. 2B further illustrates the photodetector of FIG. 2A.

FIG. 3A illustrates another embodiment of a photodetector having an embedded contact electrode.

FIG. 3B illustrates another embodiment of a photodetector having an embedded contact electrode.

FIG. 4 illustrates one embodiment of a method of operating a photodetector.

FIG. 5 illustrates one embodiment of an x-ray detection system.

FIG. 6A illustrates one embodiment of a method of making a photodetector having an embedded electrode within a semiconductor material.

FIG. 6B illustrates another embodiment of a method of making a photodetector having an embedded electrode within a semiconductor material.

FIG. 7A illustrate one embodiment of a photodetector with an embedded mesh contact electrode within semiconductor material.

FIG. 7B further illustrates the embodiment of FIG. 7A.

FIG. 7C further illustrates the embodiment of FIG. 7A.

FIG. 8A illustrates one embodiment of a fiber mesh as an embedded contact electrode.

FIG. 8B illustrates another embodiment of a mesh as an embedded contact electrode.

FIG. 9 illustrates one embodiment of equipotentials between the two contact electrodes when the aperture width of the mesh is comparable to the mesh-to-second contact distance.

FIG. 10 illustrates equipotentials when the aperture width of the mesh is 20% smaller than the mesh-to-second contact distance.

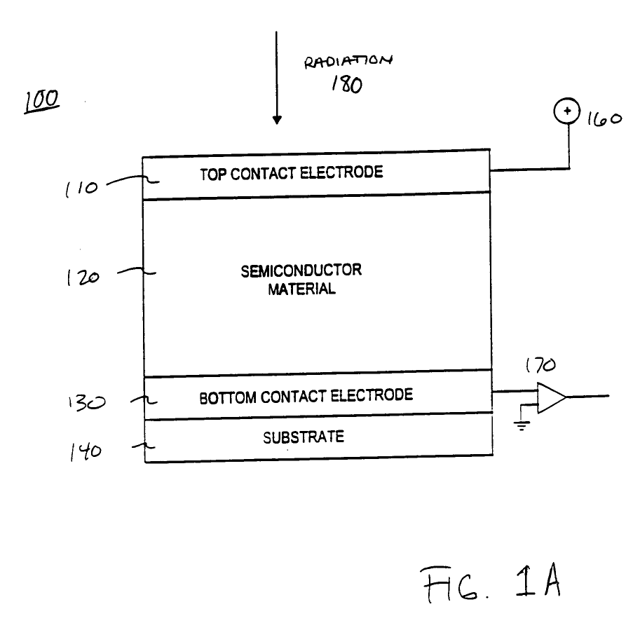

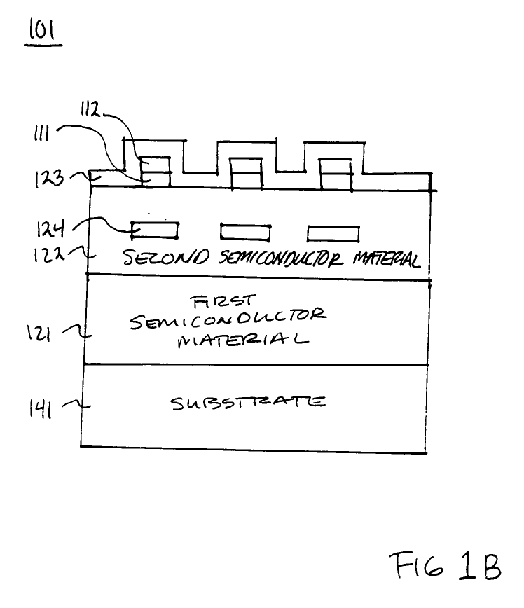

### DETAILED DESCRIPTION

In the following description, numerous specific details such as specific materials, processing parameters, processing steps, etc., are set forth in order to provide a though understanding of the invention. One skilled in the art will recognize that these details need not be specifically adhered to in order to practice the claimed embodiments. In other instances, well known processing steps, materials, etc., are not set forth in order not to obscure the invention.

The terms “top,” “bottom,” “front,” “back,” “above,” “below,” and “between” as used herein refer to a relative position of one layer or component with respect to another. As such, one layer deposited or disposed above or below another layer, or between layers, may be directly in contact with the other layer(s) or may have one or more intervening layers. The term “coupled” as used herein means coupled directly to, or indirectly through one or more intervening components. The term “charge carriers” is often used to refer to either the electrons, or holes, or both. The term “electrode” as used herein means a collector or emitter of electric charge or electric-charge carriers, as in a semiconductor device or a solid electric conductor through which an electric current enters or leaves a medium, as an electrolyte, a nonmetallic solid, a molten metal, a gas, or a vacuum. The term “embed” as used herein means to fix firmly in a surrounding mass or to enclose snugly or firmly or to cause to be an integral part of a surrounding whole. The term “mesh” as used herein means an openwork fabric or structure, a net or network, or any of the open spaces in a net or network or the wires surrounding these spaces.

A photodetector having an embedded contact electrode structure is described that may operate to reduce contact corrosion and/or reduce contact adhesion problems and/or reduce inconsistent contact characteristics. In one particular embodiment, for example, the photodetector includes a substrate, a first contact electrode, a semiconductor material, and a second contact electrode. The second contact electrode is coupled to the substrate and the semiconductor material and the first contact electrode is embedded within the semiconductor material. An advantage of such a structure is that the embedded contact electrode provides mechanical flexibility to accommodate expansion mismatch between the photoconductor material and the embedded contact electrode, while providing an essentially continuous plane of contact as a conductor.

In one embodiment, the embedded contact electrode has apertures in it to enable the semiconductor material to pass through it to some extent during the deposition of the embedding portion. By this means the semiconductor material embeds the contact electrode within the semiconductor material. In one embodiment, both these requirements may be achieved by using a mesh for the contact electrode. The mesh may be comprised of carbon fibers, which may be straight or crimped, and may accommodate expansion and contraction, while providing an essentially continuous plane of contact as a conductor.

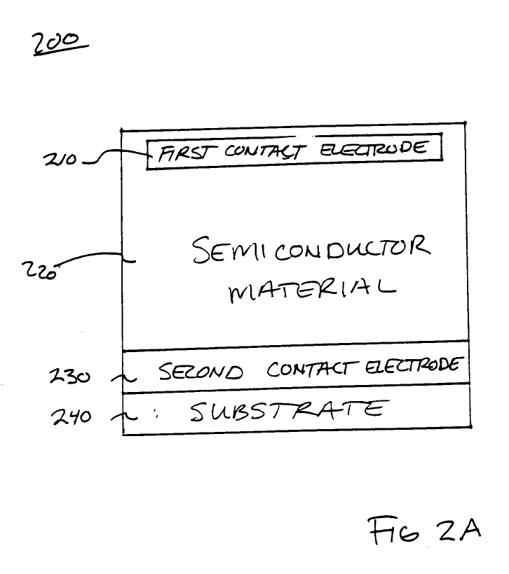

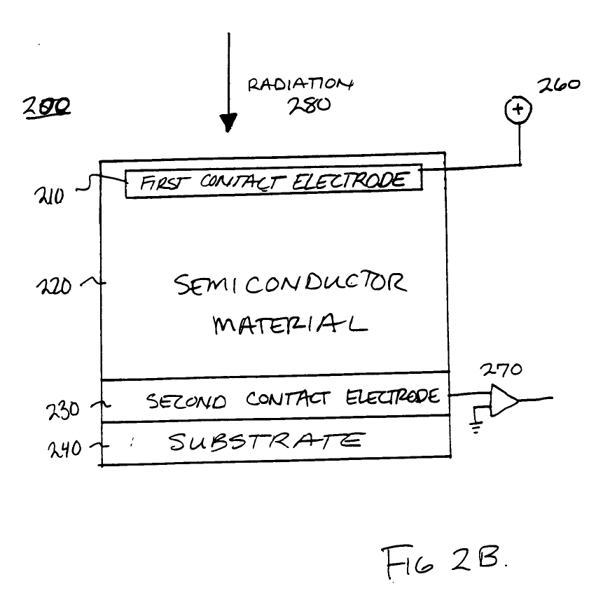

FIG. 2A illustrates one embodiment of a photodetector having an embedded contact electrode within a semiconductor material 220. In this embodiment, photodetector 200 includes a semiconductor material 220, a first contact electrode 210 embedded within the semiconductor material 220, a second contact electrode 230 coupled to the semiconductor material 220, and a substrate 240 coupled to the second contact electrode 230. The first and second contact electrodes 210 and 230 may be constructed from conducting materials, for examples, carbon, palladium, and indium tin oxide (ITO). Alternatively, other conducting materials such as aluminum may be used. It should be noted that the semiconductor material 220 may be passivated as known to one of ordinary skill in the art. In one embodiment, substrate 240 may be glass. Alternatively, other materials may be used for substrate 240.

In one embodiment, the semiconductor material 220 may be mercuric iodide (HgI2). In other embodiments, the semiconductor material 220 may be lead iodide (PbI2), bismuth iodide (Bil3), thallium bromide (Tl₂Br₄). Similarly, other conductors, such as various metals like, nickel, palladium, aluminum, and carbon, for example) may be used as the embedded contact electrode within the semiconductor material 220. In another embodiment, the metals may have a thin layer of electrically conductive protective material deposited upon their surface, (for example a layer of carbon, deposited by sputtering) to prevent any chemical interaction with the iodide. In another embodiment, the contact electrode comprising of a mesh of carbon fibers may be coated with silicon carbide. An advantage of such a structure is that the contact electrodes coated with protective material deposited upon their surface may be protected from chemical attack by the mercuric iodide layer.

FIG. 2B further illustrates the photodetector 200 of FIG. 2A. In this embodiment, photodetector 200 includes all the elements as described in FIG. 2A. The semiconductor material 220, upon which radiation 280 is incident through the first contact electrode 210, acts as a direct conversion layer to convert incident radiation 280 to electric currents. A voltage source 350 connected to the electrodes applies a positive bias voltage across the semiconductor material 220, and current is observed as an indication of the magnitude of incident radiation 280. When no radiation 280 is present, the resistance of the semiconductor material 220 is high for most photoconductors, and only a small dark current can be measured. When radiation 280 is made incident through the first contact electrode 210 within the semiconductor material 220, electron-hole pairs form and drift apart under the influence of a voltage across that region. Electrons are drawn toward the more positively (+) biased contact electrode, the first contact electrode 210, and holes are drawn toward the more negatively biased (e.g., quasi-grounded by circuitry 270) second contact electrode 230. Formation of electron-hole pairs occurs due to interaction between the incident radiation and the semiconductor material 220. If radiation 280 (x-rays) has energy greater than the band gap energy of the semiconductor material 220, then electron-hole pairs are generated in the semiconductor as each photon is absorbed in the material. If a voltage is being continuously applied across the semiconductor material 220, the electron and hole will tend to separate, thereby creating a current flowing through the photodetector 200. The magnitude of the current produced in the photodetector 200 is related to the magnitude of the incident radiation 280 received. After removal of the incident radiation 280, the charge carriers (electrons and holes) remain for a finite period of time until they either reach the collection electrodes (first and second contact electrodes 210 and 230) or can be recombined.

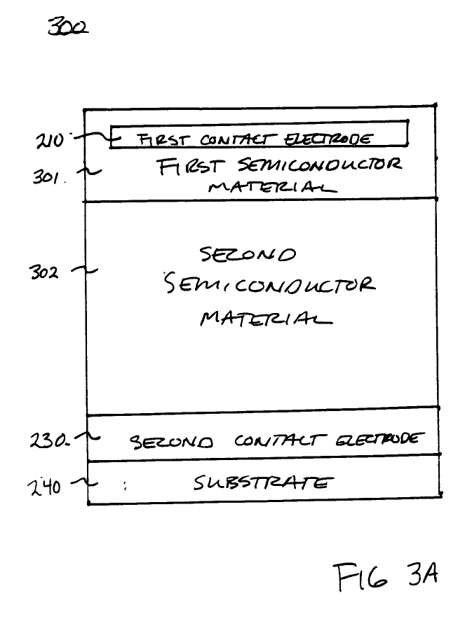

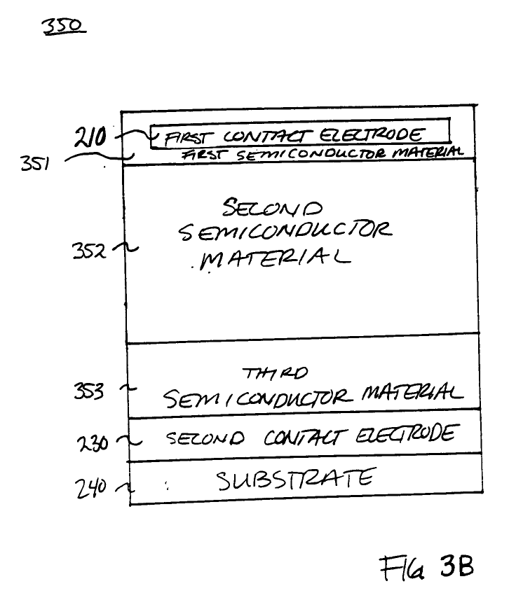

FIG. 3A illustrates another embodiment of a configuration of a photodetector with an embedded contact electrode within the semiconductor material 301. In this embodiment, photodetector 300 includes a first semiconductor material 301, a first contact electrode 210 embedded within the first semiconductor material 301, a second contact electrode 230, a second semiconductor material 302 coupled to the first semiconductor material 301, the second contact electrode 230, and a substrate 240 coupled to the second contact electrode 230. The first and second contact electrodes 210 and 230 may be constructed from conducting materials, for examples, carbon, palladium, and indium tin oxide (ITO). Alternatively, other conducting materials such as aluminum may be used. It should be noted that the semiconductor materials may be passivated as known to one of ordinary skill in the art.

In one particular embodiment, first semiconductor material 301 may be composed of lead iodide (PbI₂) and second semiconductor material 302 may be composed of mercuric iodide (HgI₂). The second semiconductor material 302 (HgI₂) is preferably thicker than the first semiconductor material 301 (PbI₂). Mercuric iodide (HgI₂) may have superior properties for x-ray detection, making its inclusion in one embodiment of photodetector 300 advantageous. However, use of mercuric iodide (HgI₂) as a semiconductor material, by itself, in a photodetector may be problematic, as it may be chemically reactive with one or both conductors (first contact electrode 210 and second contact electrode 230). As such, a thin layer of lead iodide (PbI₂) (first semiconductor material 301) may be used as a buffer between the second semiconductor material 302 (HgI₂) and the embedded first contact electrode 210 to reduce chemical reactive effects, while allowing the thicker mercuric iodide (HgI₂) layer to dominate the performance characteristics of the heterojunction structure.

Various thickness relationships between the first semiconductor material 301 (PbI₂) and the second semiconductor material 302 (HgI₂) may be used. For example, first semiconductor material 301 may be thin and the second semiconductor material 302 thick, relative to each other. The advantage of this structure is the addition of a first semiconductor material 301 between the second semiconductor material 302 and the first contact electrodes 210 may reduce the chemical reaction between the second semiconductor material 302 (HgI₂) and the first contact electrodes 210 by providing a less corrosive interface.

In one embodiment, first semiconductor material 301 may have a thickness less than 300 microns (μm), for examples, 10, 40 or 150 microns. The second semiconductor material 302 may have a thickness greater than 350 microns, for examples, 200, 350 or 450 microns. Note that the specific thickness need not be matched up respectively, such that 10 microns for the first semiconductor material thickness and 450 microns for the second semiconductor thickness may be used together. In another embodiment, two relatively medium thickness layers (such as two 150 micron layers for example) may be used. In an alternative embodiment, the first semiconductor material 301 may be thicker than second semiconductor material 302, for example, to further remove second semiconductor material 302 from the first contact electrode 210. It should be noted that the semiconductor materials may have thickness outside the exemplary ranges provided above and, in particular, the primary detection material (e.g., second semiconductor material 302) depending on the particular application (e.g., mammography, general radiography, industrial, etc.) in which photodetector 300 will be used. For example, first semiconductor material 301 may have a thickness on the order of Angstroms and the second semiconductor material 302 may have a thickness on the order of millimeters.

In one embodiment, first semiconductor material 301 (e.g., the PbI₂ layer) is thinner than second semiconductor material 302 (e.g., the HgI₂ layer). The resulting structure may be expected to have the properties of mercuric iodide (HgI₂) for detection purposes, without the corresponding reactive properties of a single layer, mercuric iodide (HgI₂) photodetector.

In alternative embodiments, semiconductor materials other than mercuric iodide and lead iodide may be used, such as other semiconductor halides, for example. In one embodiment, such alternative materials may be iodide compounds such as bismuth iodide (BiI₂). Alternatively, non-iodide compounds and may be used, for example, thallium bromide (TlBr). The semiconductor materials selected for use may operate as a corrosion barrier layer to a contact electrode and/or as part of the heterojunction structure to optimize the electric parameters of the detector (e.g., reduce dark currents). The other semiconductor materials that may be used for the first and second semiconductor materials 301 and 302 may have band gaps approximately the same or different than either of mercuric iodide (2.1 eV) and lead iodide (2.3 eV). For example, bismuth iodide has a band gap of 1.73 eV and thallium bromide has a band gap of 2.7 eV. As previously noted, other halides may also be used for the semiconductor materials 301 and 302.

FIG. 3B illustrates another embodiment of a configuration of a photodetector with an embedded contact electrode. In this embodiment, photodetector 350 includes a first semiconductor material 351, a first contact electrode 210 embedded within the first semiconductor material 351, a second semiconductor material 352 coupled to the first semiconductor material 351, a third semiconductor material 353 coupled to the second semiconductor material 352, a second contact electrode 230 coupled to the third semiconductor material 353, and a substrate 240 coupled to the second contact electrode 230. The first and second contact electrodes 210 and 230 may be constructed from conducting materials, for examples, carbon, palladium, and indium tin oxide (ITO). Alternatively, other conducting materials such as aluminum may be used. It should be noted that the semiconductor materials may be passivated as known to one of ordinary skill in the art.

In one embodiment, both first and third semiconductor materials 351 and 353 (e.g., the PbI₂ layers) are thinner than second semiconductor material 352 (e.g., the HgI₂ layer). The resulting structure may be expected to have the properties of mercuric iodide (HgI₂), for detection purposes, without the corresponding reactive properties of a single layer, mercuric iodide (HgI₂) photodetector. In an alternative embodiment, the first and third semiconductor material 351 and 353 may be thicker than second semiconductor material 352, for example, to further remove second semiconductor material 352 from the first contact electrode 210 and the second contact electrode 230. The advantage of the sandwich structure is the sandwich structure may reduce the chemical reaction between the second semiconductor material 352 and provides a less corrosive interface with the first and second contact electrodes 210 and 230.

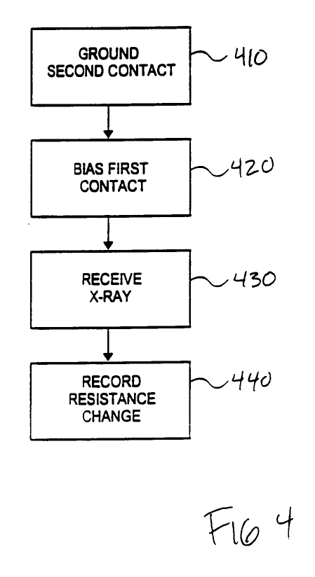

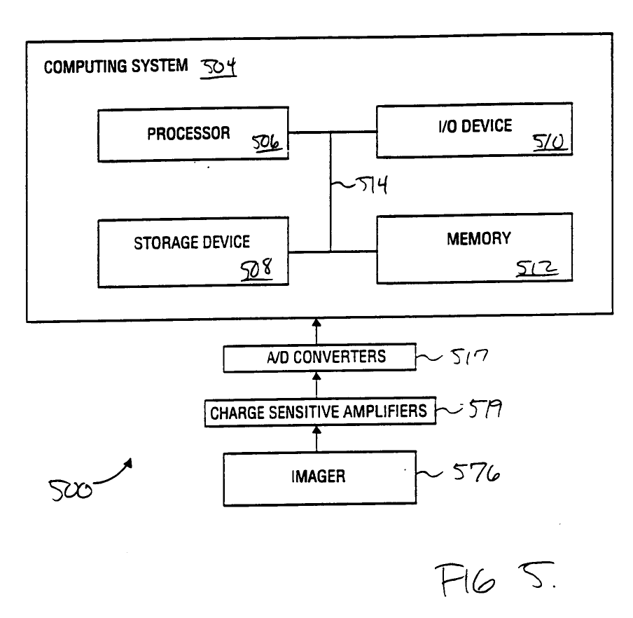

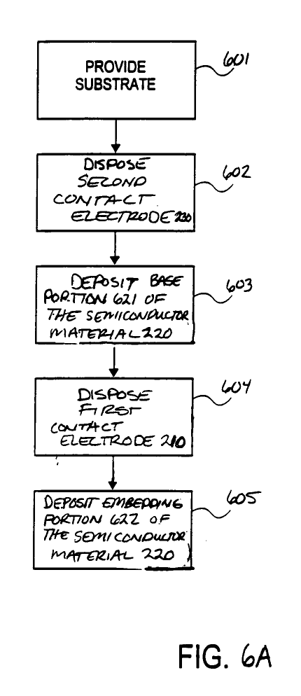

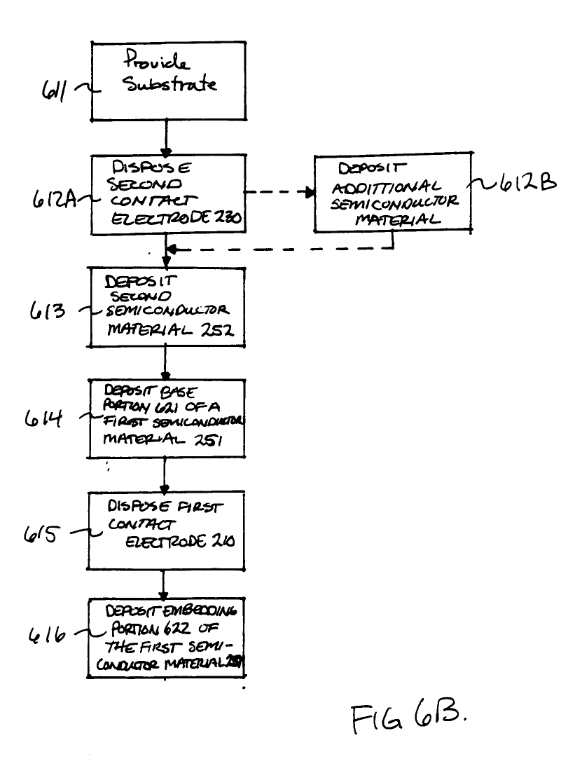

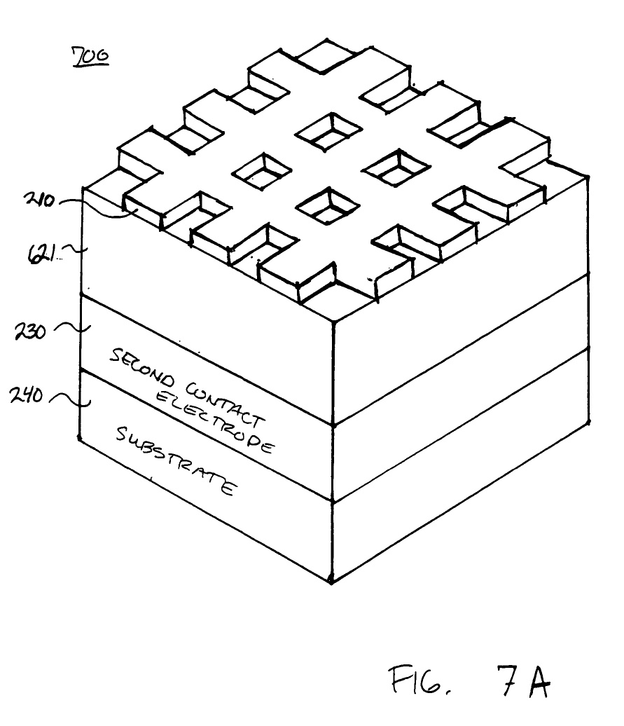

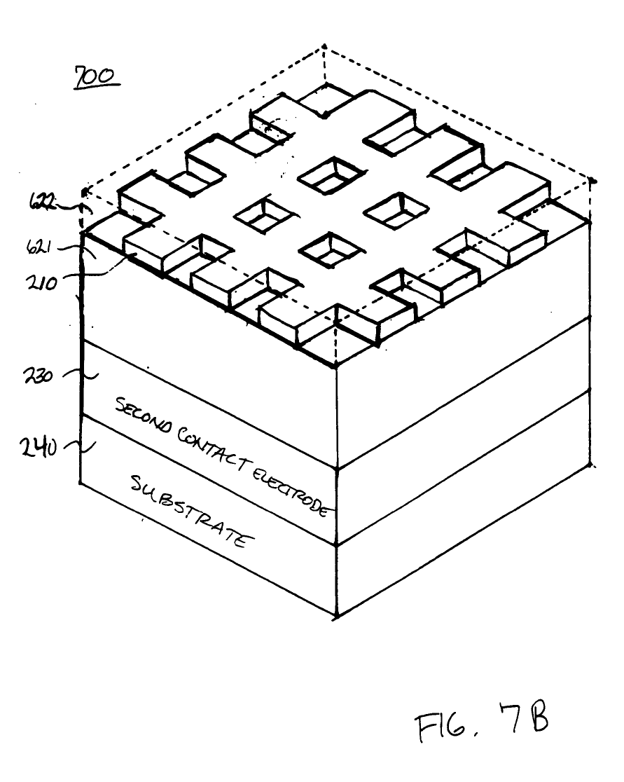

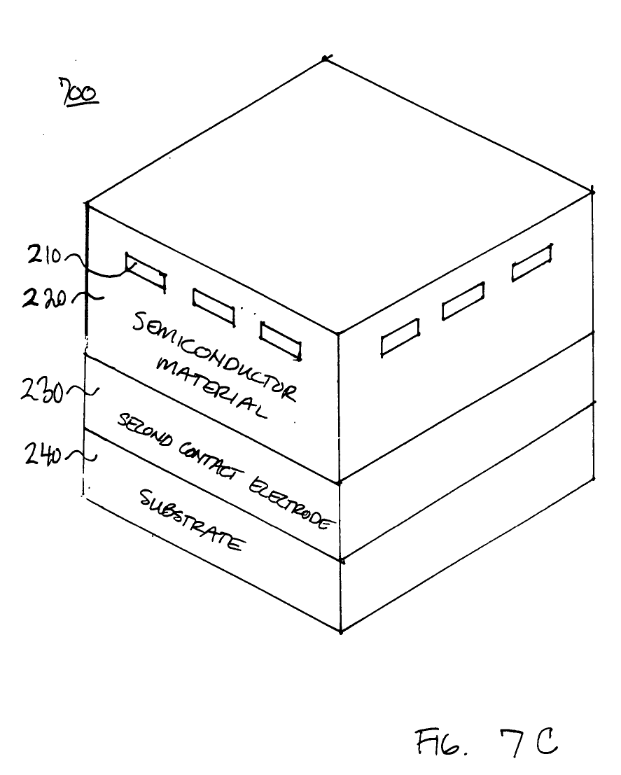

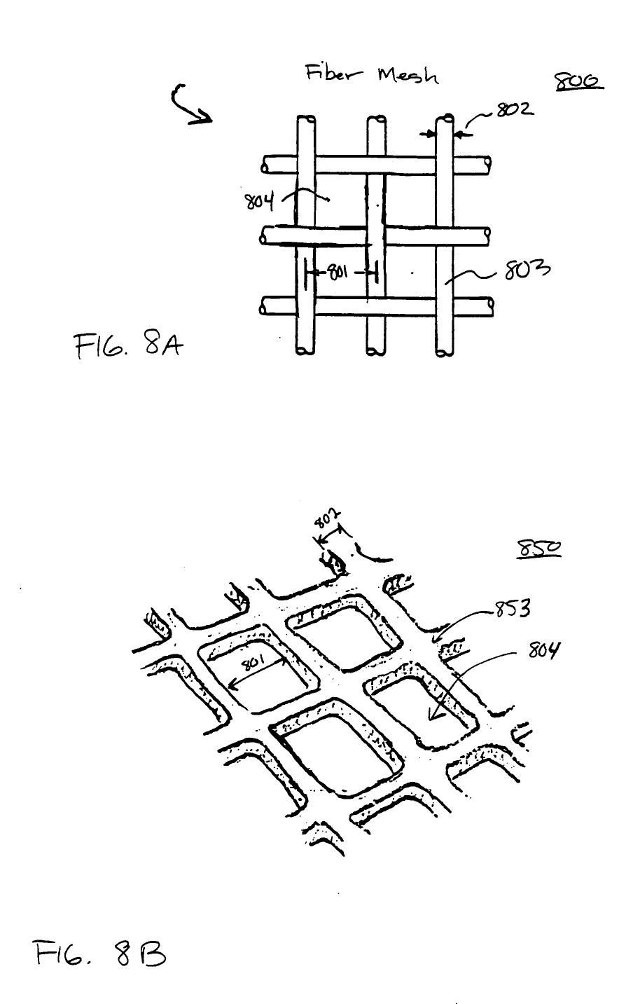

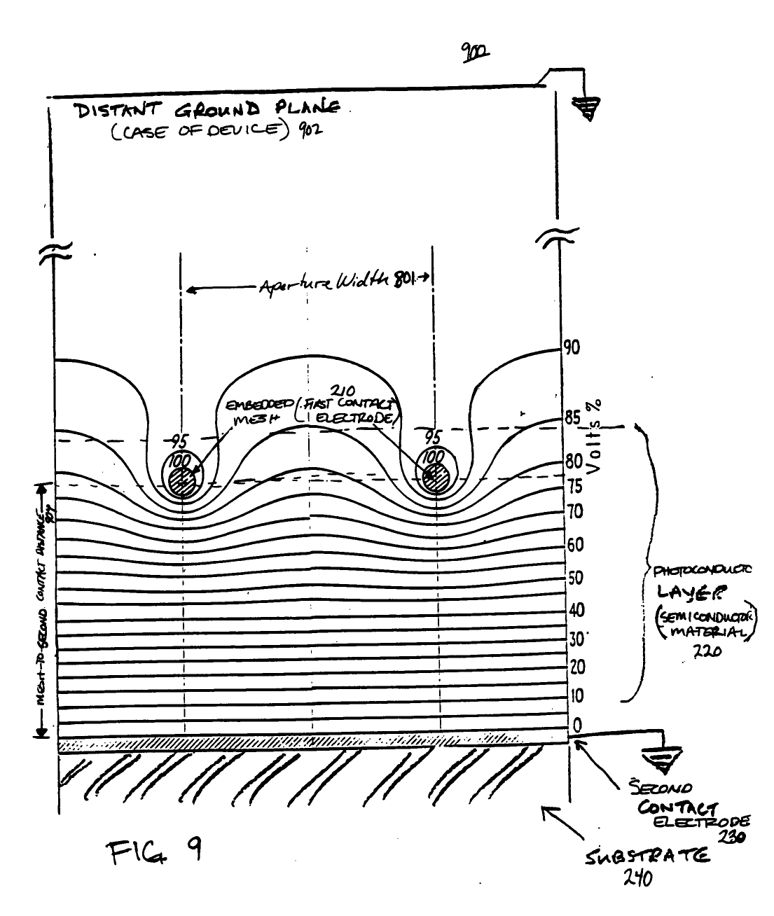

FIG. 4 illustrates one embodiment of a method of operating photodetector 300. At block 410, second contact electrode 230 is coupled to ground. At block 420, first contact electrode 210 is biased to a negative voltage. At block 430, photodetector 300 is oriented such that x-rays (radiation 280) are received through first contact electrode 210. Alternatively, other biases and x-ray receipt configuration may be used. At block 440, a surrounding imaging system 500 records the change in resistance (as a current or voltage change) and thereby registers the presence of the X-ray. In one embodiment, an x-ray detector 576 may be constructed, for example, as a flat panel detector with a matrix of photodetectors 300 with readout electronics to transfer the light (e.g., x-ray) intensity of a pixel to a digital signal for processing. The readout electronics may be disposed around the edges of the detector to facilitate reception of incident x-rays on either surface of the detector. The flat panel detector may use, for example, TFT switch matrix coupled to the detectors 200 and capacitors to collect charge produced by the current from detectors 200. The charge is collected, amplified and processed as discussed below in relation to FIG. 5. The choice of bias voltage may determine the sensitivity of the detector 200. The bias voltage may be configured by system 500 of FIG. 5.

FIG. 5 illustrates one embodiment of an x-ray detection system. X-ray detection system 500 includes a computing device 504 coupled to a flat panel detector 576. As previously mentioned, flat panel detector 576 may operate by accumulating charge on capacitors generated by pixels of photodetector 200. Typically, many pixels are arranged over a surface of flat panel detector 576 where, for example, TFTs at each pixel connect a charged capacitor (not shown) to charge sensitive amplifier 519 at the appropriate time. Charge sensitive amplifier 519 drives analog to digital (A/D) converter 517 that, in turn, converts the analog signals received from amplifier 519 into digital signals for processing by computer device 504. A/D converter 517 may be coupled to computing device 504 using, for example, I/O device 510 or interconnect 514. A/D converter 517 and charge sensitive amplifiers 519 may reside within computing device 504 or flat panel detector 576 or external to either device. Amplifiers 519 integrate the charges accumulated in the pixels of the flat panel detector 576 and provide signals proportional to the received x-ray dose. Amplifiers 519 transmit these signals to A/D converter 517. A/D converter 517 translates the charge signals to digital values that are provided to computing device 504 for further processing. Although the operation of switch matrix may be discussed herein in relation to a TFT matrix, such is only for ease of discussion. Alternatively, other types of switch devices, such as switching diodes (e.g., single and/or double diodes) may also be used.

FIG. 6A illustrates one embodiment of a method of making a photodetector 200 having an embedded first contact electrode 210 within a semiconductor material 220. In step 601, substrate 240 (e.g., composed of glass) is provided. In step 602, second contact electrode 230 is disposed on the substrate 240 using any one of various techniques that are known in the art, for examples, coating, plating, chemical vapor deposition (CVD), sputtering, ion beam deposition, etc. In step 603, a base portion 621 of semiconductor material 220 (e.g., PbI₂) is deposited above the second contact electrode 230. In step 604, a first contact electrode 210 is disposed on the semiconductor material 220. In step 605, an embedding portion 621 of the semiconductor material 220 is deposited above the first contact electrode 210. Step 605 embeds the first contact electrode 210 within the semiconductor material 220. It should be noted that electrical connections may be made to the first contact electrode 210 at the periphery of the semiconductor material 220.

One method of fabricating a photodetector with an embedded mesh comprises depositing the mesh above the base portion 621 of the semiconductor material 220 after deposition, and then, depositing an embedding portion 622 of semiconductor material 220 over the mesh of carbon fibers. The mesh contact electrode allows the embedding portion 622 of semiconductor material 220 to pass through the apertures of the mesh so that the embedding portion 622 of semiconductor material 220 becomes in intimate contact with the base portion 621 of the semiconductor material 220 below the mesh. Electrical connections may be made to the carbon fiber mesh at the periphery of the semiconductor material 220.

In one particular embodiment, for example, the photodetector includes a layer of lead iodide (PbI₂) and a thicker layer of mercuric iodide (HgI₂) disposed above to form a bi-layer PbI₂—HgI₂ coating film (illustrated in FIG. 3A). A thin layer of lead iodide may also be disposed above the mercuric iodide layer to form a three-layer PbI₂—HgI₂—PbI₂ “sandwich” structure (illustrated in FIG. 3B). The contact electrode may be embedded within the thin layer of lead iodide. Alternatively, other semiconductor materials may be used for any of the layers as discussed below.

An advantage of such a structure is that the outer contacts on the coating film may be protected from chemical attack by the mercuric iodide material because of the presence of the intervening semiconductor material(s) of relatively unreactive lead iodide, while maintaining a high mobility in the photoconductor due to the thicker higher mobility material. As such, by using a thicker material of mercuric iodide, the overall carrier transport properties of the photoconductor may be dominated by the mercuric iodide material that constitutes the bulk of the photodetector's thickness. The term “thickness” as used herein refers to the height of the semiconductor material along the axis perpendicular to the substrate 240.

Another advantage of such a structure is that the embedded contact electrode may accommodate expansion and contraction of the semiconductor material 220.

FIG. 6B illustrates another embodiment of a method of making a photodetector 300 having an embedded first contact electrode 210 within the semiconductor material 301. The method involves fabrication of photodetectors, such as those previously illustrated, with a heterojunction structure. In step 611, substrate 240 (e.g., composed of glass) is provided. In step 612A, second contact electrode 230 is disposed on the substrate 240 using any one of various techniques that are known in the art, for examples, coating, plating, chemical vapor deposition (CVD), sputtering, ion beam deposition, etc. In step 613, a second semiconductor material 302 (e.g., HgI₂) is deposited above the second contact electrode 230. In step 614, a base portion 621 of a first semiconductor material 301 (e.g., PbI₂) is deposited above the second semiconductor material 302. The first and second semiconductor materials 301 and 302 may be deposited using any one of various techniques known in the art, for examples, chemical vapor deposition (CVD), sputter, ion beam deposition, etc. In step 615, a first contact electrode 210 is disposed on the base portion 621 of the first semiconductor material 301. In step 616, an embedding portion 622 of the first semiconductor material 301 is deposited above the first contact electrode 210. Step 616 embeds the first contact electrode 210 within the first semiconductor material 301. It should be noted that electrical connections may be made to the first contact electrode 210 at the periphery of the first semiconductor material 301.

In an alternative embodiment, as discussed above, the photoconductor may include additional semiconductor materials. In one such embodiment, a third semiconductor material 353 is deposited above the second semiconductor material 352, step 612B, thereby sandwiching the second semiconductor material 352 between the first and third semiconductor materials 351 and 353. In this particular embodiment, the first contact electrode 210 may be embedded within the first semiconductor material 351.

It should be noted that the processes illustrated in FIGS. 6A, 6B, and 6C are simplified, and may involve patterning (such as for isolation of individual conductors for example). Furthermore, a self-aligned process may be used, in which individual detectors are separated out through etching of some form after formation of layers on the substrate 240.

FIGS. 7A, 7B, and 7C illustrate one embodiment of a photodetector 700 comprising a contact electrode 210 embedded within the semiconductor material 220. FIG. 7A further illustrates steps 601-604 of FIG. 6A. In this embodiment, the photodetector 700 comprises a mesh for a first contact electrode 210, a substrate 240, a second contact electrode 230, and a base portion 621 of semiconductor material 220. As described in relation to FIG. 6A, a substrate 240 is provided, step 601. The second contact electrode 230 is disposed on the substrate 240 using any one of various techniques that are known in the art, for examples, coating, plating, chemical vapor deposition (CVD), sputtering, ion beam deposition, etc., step 602. A base portion 621 of the semiconductor material 220 is deposited above the second contact electrode 230, step 603. The mesh contact electrode 210 is disposed on the base portion 621 of the semiconductor material 220, step 604. Semiconductor material 220 comprises two portions of semiconductor material, a base portion 621, and an embedding portion 622. FIG. 7B further illustrates the depositing of the embedding portion 622 of the semiconductor material 220, as described in relation to step 605 of FIG. 6A. FIG. 7C illustrates how step 605 of FIG. 6A, depositing the embedding portion 622 of the semiconductor material 220 on the first contact electrode 210, embeds the first contact electrode 210 (the mesh) within the semiconductor material 220.

FIG. 8A illustrates one embodiment of a fiber mesh 800 as the embedded contact electrode 210. In this embodiment, the fiber mesh 800 comprises woven fibers 803. Each fiber of the woven fibers 803 has a mesh width 802. In this particular embodiment, the mesh width 802 is the diameter of the fibers. The woven fiber mesh comprises apertures 804 with an aperture width 801. The aperture width 801 is the distance between each fiber along the axis parallel to the substrate 240. In this particular embodiment, the apertures have a substantially square shape. In another embodiment, the apertures 804 may have another shape, for examples, a rectangular shape, a circular shape, a triangular shape, and/or a hexagonal shape. Carbon may be particularly suitable for the woven fibers 803 because of the availability of fine carbon fiber and woven carbon fiber mesh or cloth, and may also be a practical method for metal mesh that can be woven from fine wire.

In one embodiment, the carbon fibers of the fiber mesh 800 may be crimped so that the fiber mesh 800 may accommodate expansion and contraction of the semiconductor material 220, since the individual carbon fibers have a very low longitudinal coefficient of thermal expansion. The aperture width 801 of the apertures 804 of the fiber mesh 800 may be sized relative to the thickness of the semiconductor material 220 so that a uniform polarizing voltage gradient with planar equipotentials is generated through the semiconductor material 220 when a voltage is applied to the fiber mesh 800. The term “thickness” as used herein refers to the height of the semiconductor material 220 along the axis perpendicular to the substrate 240. The term “width” as used herein refers to the distance between the woven fibers 803 of the fiber mesh 800 along the axis parallel to the substrate 240. The aperture width 801 and the mesh width 802 of the fiber mesh 800 may also be chosen so that the semiconductor material 220 is disposed through the apertures 804 to sufficiently embed the woven fibers 803 of the fiber mesh 800 within the semiconductor material 220. The aperture width 801 and the mesh width 802 of the fiber mesh 800 may also be chosen so that the fiber mesh 800 may provide a conductor having an essentially continuous plane of contact.

In another embodiment, in order to modify the contact properties of the carbon fibers, the fibers may be coated with layer of another material, for example, other stable and unreactive conductors such as silicon carbide. The carbon fibers may also be coated with a layer of metal. The coated embedded carbon fibers may be made exceedingly thin to provide advantages over conventional metal contacts.

FIG. 8B illustrates another embodiment of a mesh 850 as the embedded contact electrode 210. In this embodiment, the mesh 850 comprises a continuous thin foil 853 with apertures 804. Apertures 804 have an aperture width 801. Continuous thin foil 853 has a mesh width 802. In this particular embodiment, the apertures 804 have a substantially rectangular shape. In another embodiment, the apertures 804 may have another shape, for examples, a square shape, a circular shape, a triangular shape, and/or a hexagonal shape. Alternatively, other shapes may be used. In one embodiment, the apertures 804 may be photo-etched (chemically milled) from the continuous thin foil 853. In another embodiment, the apertures may be formed using other methods known to one of ordinary skill in the art.

In another embodiment, the contact electrode may comprise a mesh formed from a continuous sheet of starting material, such as nickel or palladium, which has been formed into a thin foil. The thin foil includes an array of apertures forming the mesh. One example of a process to form the array of apertures in the thin foil may be photo-etching (chemical milling). Photo-etching the continuous thin foil leaves a large-area sheet of metal mesh with narrow webs between a large number of small equally spaced apertures. The array of apertures may have, for examples, a substantially square shape, rectangular shape, circular shape, triangular shape, or hexagonal shape. Alternatively, other shapes may be used. In one embodiment, the aperture width 801 of the mesh may be 20% smaller than the thickness of the semiconductor material 220. Alternatively, other ratios of aperture width 801 to thickness of the semiconductor material 220 may be used.

In one embodiment, the aperture width 801, relative to the thickness of the semiconductor material 220 may be chosen to provide an electrostatic field in the semiconductor material 220 approximately equivalent to that which would arise from a continuous conducting sheet. The carbon mesh conductor may be embedded, thus alleviating any bonding or fracturing problems inherent in use of a layer formed completely outside the semiconductor material 220. The apertures width 801 and mesh width 802 may be chosen in order to sufficiently embed the mesh within the semiconductor material 220. It should be noted that electrical connections may be made to the mesh contact electrode at the periphery of the semiconductor material 220. In one embodiment, electrical connections may be available at the edges of the detector. In another embodiment, the electrical connections may be made through vias in the semiconductor material 220. Alternatively, other methods known by one of ordinary skill in the art may be used to make electrical connections between the contact electrode and the voltage source 350 and/or the circuitry 270.

FIG. 9 illustrates one embodiment equipotentials between the two contact electrodes when the aperture width 801 of the mesh is comparable to the mesh-to-second contact distance 904. In this embodiment, photodetector 900 comprises a substrate 240, a second contact electrode 230, a photoconductor material (semiconductor material 220), an embedded mesh (first contact electrode 210), and a distant ground plane (case of device) 902. The first contact electrode 210 comprises an aperture width 801 that is approximately equivalent to the mesh-to-second contact distance 904. In this embodiment, a voltage is applied to first contact electrode 210 by voltage source 350 of FIG. 2B. The voltage applied to the first contact electrode 210 creates regions of equipotentials. The equipotentials are in terms of a voltage percentage, 100% voltage at the first contact electrode 210, and 0% voltage at the second contact electrode 230. The equipotentials between the two contact electrodes are illustrated in 10% level increments through the semiconductor material 220.

In one embodiment, the aperture width 801 of the mesh may be approximately 20% smaller than the thickness of the semiconductor material 220 in order to have the field penetration effects be negligible. One example of this embodiment is a semiconductor material 220 having a thickness of approximately 100 microns. It should be noted that the semiconductor material 220 may range up to many hundreds of microns in thickness depending upon the energy of the x-ray photons expected in the photodetector application. In this example, the aperture width 801 of the mesh is approximately 20 microns to be 20% smaller than the 100 micron thickness of the semiconductor material 220. Carbon fibers may be obtained in fiber diameters (mesh width 802) as small as 5 to 7 microns and may be woven into mesh with an average spacing between fibers (aperture width 801) as small as 10 microns. Any fluctuations in the electric field at the surface of the second contact electrode resulting from the presence of the apertures of the mesh may have a spatial extent considerably smaller than the pixel pitch in an x-ray imager, which would be 50 microns or more. Therefore, any pixel-to-pixel variations in the uniformity of collection of charge carriers on the second contact electrode may be reduced.

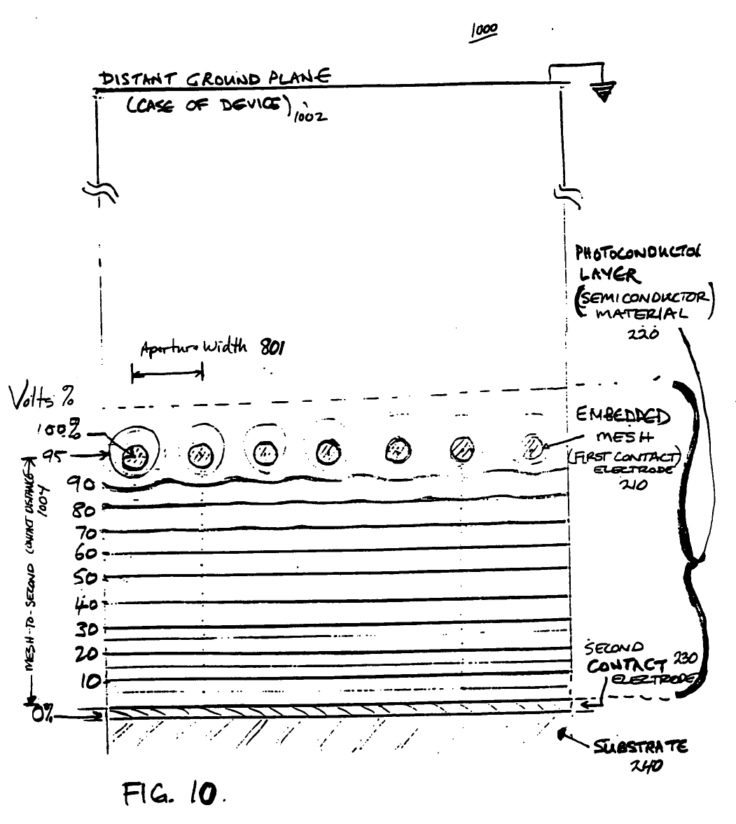

FIG. 10 illustrates one embodiment of equipotentials between the two contact electrodes when the aperture width 801 is approximately 20% of the mesh-to-second contact distance 1004. In this embodiment, photodetector 1000 comprises a substrate 240, a second contact electrode 230, a photoconductor material (semiconductor material 220), an embedded mesh (first contact electrode 210), and a distant ground plane (case of device) 1002. The first contact electrode 210 comprises an aperture width 801 that is approximately equivalent to the mesh-to-second contact distance 1004. In this embodiment, a voltage is applied to first contact electrode 210 by voltage source 350 of FIG. 2B. The voltage applied to the first contact electrode 210 creates regions of equipotentials. The equipotentials are in terms of a voltage percentage, 100% voltage at the first contact electrode 210, and 0% voltage at the second contact electrode 230. The equipotentials between the two contact electrodes are illustrated in 10% level increments through the semiconductor material 220. FIG. 10 illustrates that when the aperture width 801 are approximately 20% of the mesh-to-second contact distance 1004 the first contact electrode 210 (the embedded mesh) creates planar equipotentials throughout the photoconductor layer (semiconductor material 220). An advantage of such a structure is the embedded mesh (first contact electrode 210) may electrically behave as a conductor having an essentially continuous plane of contact. In one embodiment, the charge carriers may not pass through the embedded mesh when they are detected. The electrical behavior of the charge carriers in response to the embedded mesh may be as if the mesh were a continuous sheet of metal, and thus, the mesh does not require a high degree of optical transparency. The mesh may have a screening factor (a measure of the open area) of 50%.

In the foregoing detailed description, the method and apparatus of the present invention has been described with reference to specific exemplary embodiments thereof. It will, however, be evident that various modifications and changes may be made thereto without departing from the broader spirit and scope of the present invention. Moreover, the foregoing materials are provided by way of example as they represent the materials used in photodetectors. It will be appreciated that other semiconductor materials or other electrode materials may be used. Any electrode material that is less reactive with the semiconductor material and otherwise satisfies the desired electrical parameters may be used. The present specification and figures are accordingly to be regarded as illustrative rather than restrictive.

1. A photodetector, comprising:
a first semiconductor material; and
a first contact electrode embedded within the first semiconductor material.

2. The photodetector of claim 1, wherein the first contact electrode comprises a mesh.

3. The photodetector of claim 2, wherein the first semiconductor material is disposed through the mesh.

4. The photodetector of claim 1, wherein the first semiconductor material comprises an iodide compound.

5. The photodetector of claim 1, wherein the first semiconductor material comprises mercuric iodide.

6. The photodetector of claim 1, wherein the first semiconductor material comprises lead iodide.

7. The photodetector of claim 1, wherein the first semiconductor material comprises bismuth iodide.

8. The photodetector of claim 1, wherein the first semiconductor material comprises.

9. The photodetector of claim 1, wherein the first contact electrode comprises nickel.

10. The photodetector of claim 1, wherein the first contact electrode comprises palladium.

11. The photodetector of claim 1, wherein the first contact electrode comprises aluminum.

12. The photodetector of claim 1, wherein the first contact electrode comprises carbon.

13. The photodetector of claim 1, wherein the first contact electrode is coated with silicon carbide.

14. The photodetector of claim 1, wherein the first contact electrode is coated with metal.

15. The photodetector of claim 1, further comprising:
a substrate; and
a second contact electrode, the second contact electrode coupled to the first semiconductor material and the substrate.

16. The photodetector of claim 1, further comprising:
a second semiconductor material, the second semiconductor material coupled to the first semiconductor material.

17. The photodetector of claim 16, further comprising:
a substrate; and
a second contact electrode, the second contact electrode coupled to the second semiconductor material and the substrate.

18. The photodetector of claim 16, wherein the first semiconductor material comprises an iodide compound and the second semiconductor material comprises mercuric iodide.

19. An x-ray detector, comprising:
a flat panel detector comprising an array of photodetectors, wherein each of the photodetectors in the array comprises:
a first semiconductor material; and
a first contact electrode, the first contact electrode embedded within the first semiconductor material.

20. A method, comprising:
depositing a first contact electrode on a first portion of a first semiconductor material;
depositing a second portion of the first semiconductor material on the first contact electrode to embed the first contact electrode within the first semiconductor material.
